(19) United States
(12) Patent Application Publication
(10) Pub. No.: US 2025/0321292 A1
(43) Pub. Date: Oct. 16, 2025

(54) METHOD TO DETECT SINGLE-PHASE-TO-GROUND FAULTS IN ELECTRIC POWER SYSTEMS

(71) Applicant: Schweitzer Engineering Laboratories, Inc., Pullman, WA (US)

(72) Inventors: Yanfeng Gong, Dublin, OH (US); Gandhali P Juvekar, Lake Forest Park, WA (US); Normann Fischer, Colfax, WA (US)

(73) Assignee: Schweitzer Engineering Laboratories, Inc., Pullman, WA (US)

(21) Appl. No.: 19/173,430

(22) Filed: Apr. 8, 2025

Related U.S. Application Data
(60) Provisional application No. 63/632,071, filed on Apr. 10, 2024.

(51) Int. Cl. G01R 31/52; H02H 1/00; H02H 7/26

(52) U.S. Cl. CPC G01R 31/52; H02H 1/0007; H02H 7/26

(57) ABSTRACT

A system for detecting single-phase ground faults is presented herein. Single-phase ground faults on ungrounded or high-impedance single-grounded three-wire power systems are determined by filtering the currents and voltages components to remove noise, extracting the pure-fault current components, and computing their magnitude. The faulted feeder is determined as the one with the largest zero-sequence pure-fault current. of each phase, and filtering the pure-fault current components to remove noise. The faulted phase is determined as the phase with the largest pure-fault current magnitude compared with the other two phases. The detection may be qualified using the fault zero-sequence voltage magnitude.

### RELATED APPLICATIONS

This application claims priority to U.S. Provisional Patent Application No. 63/632,071 filed on Apr. 10, 2024, and titled DETECTING SINGLE-PHASE GROUND FAULT IN SINGLE-GROUNDED DISTRIBUTION SYSTEMS, the entirety of which is incorporated herein by reference.

### TECHNICAL FIELD

This disclosure relates to detecting single-phase-ground faults. More specifically but not exclusively, the systems and methods disclosed herein relate to the detection of a single-phase-to-ground (“SPG”) fault for three-wire distribution systems that are high-impedance single-grounded at the transformer neutral or are ungrounded.

### BRIEF DESCRIPTION OF THE DRAWINGS

Non-limiting and non-exhaustive embodiments of the disclosure are described, including various embodiments of the disclosure with reference to the figures, in which:

FIG. 1 illustrates a simplified one-line diagram of a portion of an electric power system comprising two feeders and consistent with embodiments of the present disclosure.

FIG. 2 illustrates a reverse voltage source equivalent to the fault-point voltage consistent with embodiments of the present disclosure.

FIG. 3 illustrates a diagram of the approximate pure-fault currents from an SPG fault consistent with embodiments of the present disclosure.

FIG. 4 illustrates a data flow for receiving and analyzing data consistent with embodiments of the present disclosure.

FIG. 5 illustrates a flow chart of a method for identifying SPG faults consistent with embodiments of the present disclosure.

FIG. 6 illustrates a functional block diagram of a system 600 for use in an electric power system and consistent with embodiments of the present disclosure.

In the following description, numerous specific details are provided for a thorough understanding of the various embodiments disclosed herein. However, those skilled in the art will recognize that the systems and methods disclosed herein can be practiced without one or more of the specific details, or with other methods, components, materials, etc. In addition, in some cases, well-known structures, materials, or operations may not be shown or described in detail in order to avoid obscuring aspects of the disclosure. Furthermore, the described features, structures, or characteristics may be combined in any suitable manner in one or more alternative embodiments.

### DETAILED DESCRIPTION

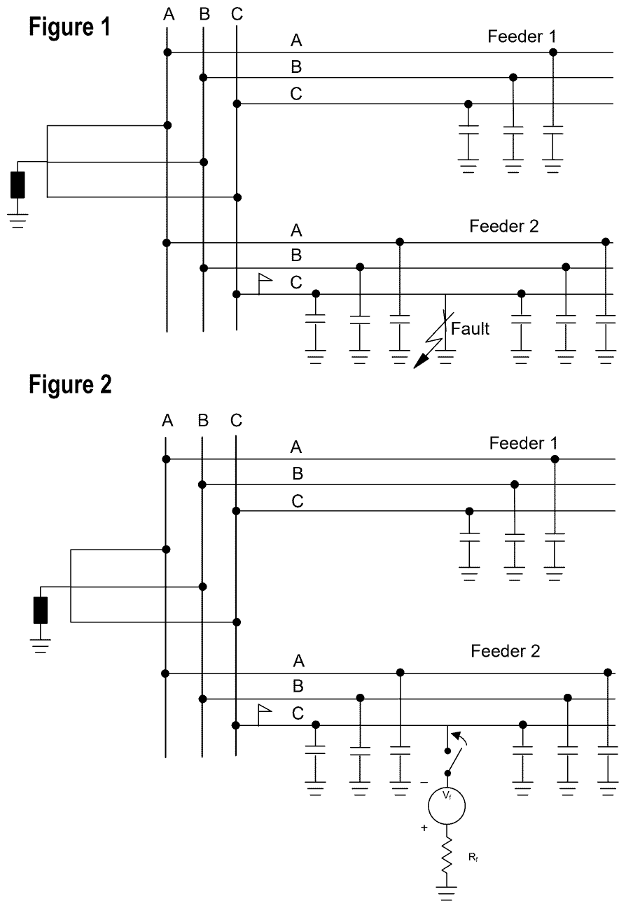

FIG. 1 illustrates a simplified one-line diagram of a portion of an electric power system comprising two feeders and consistent with embodiments of the present disclosure. While most power distribution systems in the United States are multi-grounded, four-wire systems, there are a significant amount of three-wire high-impedance-single-grounded systems like resonant-grounded systems as well as ungrounded three-wire distribution systems in the US. Ungrounded three-wire systems refer to the distribution feeders with an isolated neutral grounded at the substation and high-impedance-grounded systems refer to the distribution feeders where the transformer neutral is grounded through a high-impedance, as illustrated in FIG. 1. The high-impedance-grounding may be through a reactor for resonant-grounded systems. SPG faults on high-impedance single-grounded and ungrounded systems usually result in smaller fault currents because of no low-impedance return path.

The systems and methods disclosed herein use the relationship between pure-fault current quantities which can be computed using delta (or incremental) quantities immediately after a SPG fault occurs. The systems and methods may also use the fault-related zero-sequence voltage quantity. Systems and methods consistent with the present disclosure may use the magnitudes of these currents and voltages that arise in network after a fault to detect it.

When a single-phase-ground fault occurs on an ungrounded or a high-impedance-single-grounded three-wire feeder, the fault current is significantly less than the same fault occurs to a multi-grounded four-wire feeder because there is no low-impedance return path for the fault current to flow back to the source at the substation other than through the line charging capacitances and/or neutral reactor. It used to be the advantage of such systems because of the small fault current and no urgency of tripping the line to disrupt the service. However, in today's environment, utilities are required to reduce the wildfire hazards that are caused by power lines. Even a small fault current (e.g., a few amperes) generated by an SPG fault in such systems is enough to start a fire. SPG fault detection systems consistent with the present disclosure may mitigate against the risk of fire among other benefits discussed herein.

FIG. 2 illustrates a reverse voltage source equivalent to the fault-point voltage consistent with embodiments of the present disclosure. When an SPG fault occurs, the currents measured by the feeder relay consist of load current and fault current. Right after the fault, the pure-fault network may be approximated as having a reverse voltage source added to the location of fault. The reverse voltage source is equivalent to the fault-point voltage. Right after fault occurs, the fault network can be approximated by the linear addition of two networks: the pre-fault network and the pure-fault network. The pure-fault network may be determined by subtracting the pre-fault network from the fault network that are measured shortly after the fault, as expressed in Eq. 1, below.

$$Pure - Fault Network = ( Fault Network ) - ( Pre - Fault Network ) \qquad Eq . 1$$

The pure-fault network exists as long as the fault exists; however, the pure-fault based cannot be measured directly. Only the pre-fault network and the fault network values can be directly measured. Eq. 2 shows a relationship of pure-fault quantity over time.

$$Pure - Fault Quantity ( t ) = ( Quantity ( t ) ) - ( Quantity ( t - p ) ) \qquad Eq . 2$$

In Eq. 2, t is the time, and p is the number of cycles after a fault as an integer. The electrical parameters of a system change, and as such, the Pure-Fault Quantity (t) is relatively short-lived. For example, systems and methods consistent with the present disclosure may utilize Eq. to estimate the Pure-Fault Quantity within five (5) cycles (i.e., p<5) of the fault.

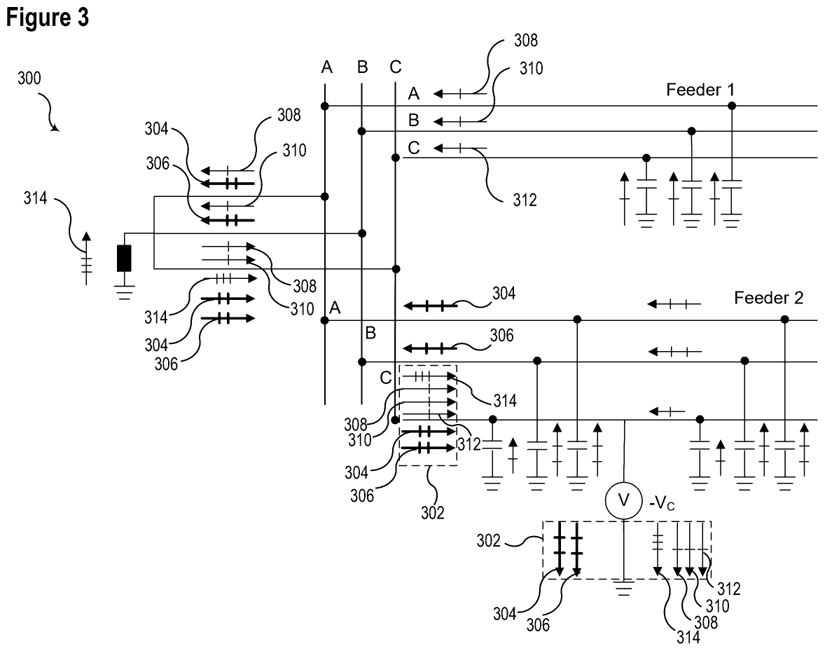

FIG. 3 illustrates a diagram of the approximate pure-fault currents from a SPG fault consistent with embodiments of the present disclosure. FIG. 3 also illustrates the approximation of the pure-fault current distribution among different phases. For AC power systems, the direction of the pure-fault currents is an illustration of the relationship between different phases.

The following observations can be made about the pure-fault network and the associated pure-fault currents:
The faulted phase (i.e., phase C) pure-fault current magnitude is larger than the other two un-faulted phases of the faulted feeder. This is illustrated by arrows 304 and 306 corresponding to the un-faulted phases (i.e., phases A and B), both contributing to the faulted phase pure-fault current as they travel to the faulted phase, and the point of the voltage source representing the fault.
The faulted phase pure-fault current, which is equal to the sum of arrows 304, 306, 308, 310, 312, and 314 (collectively identified using the dashed line identified as 302), is in the opposite direction of the pure-fault currents 304, 306 of the other two un-faulted phases of the faulted feeder.
Unfaulted feeder pure-fault phase currents 308, 310, and 312 are all in phase.
Unfaulted feeder pure-fault phase current magnitudes for all phases are smaller than the faulted phase.

These observations may be used to identify SPG faults in systems and methods consistent with the present disclosure. Moreover, such systems and methods may be used in conjunction with other protection elements (e.g., an over-current element).

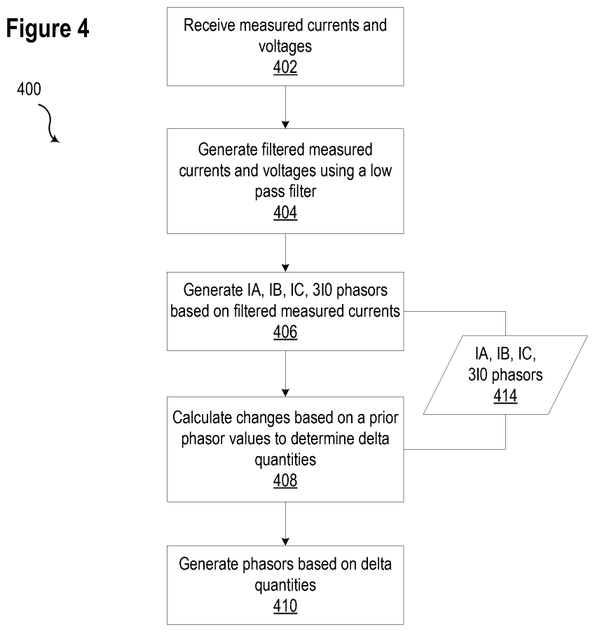

FIG. 4 illustrates a data flow 400 for receiving and analyzing data consistent with embodiments of the present disclosure. At 402, current and voltage measurements may be received that reflect electrical conditions in a three-phase power system. Some embodiments may utilize only one electrical parameter (e.g., a current measurement) for each phase, while other embodiments may utilize two or more electrical parameters. As discussed above, the electric power system may comprise a single-grounded or ungrounded three-wire system. The electrical parameters may be received from external devices (e.g., merging units), or may be collected by an IED or other type of device implementing systems and methods consistent with the present disclosure.

At 404, filtered measured currents and voltages may be generated using a low pass filter. Applying a low pass filter may remove high-frequency signals that may obscure relevant signals. Eliminating high-frequency signals may also simplify phasor analysis associated with systems and methods consistent with the present disclosure.

At 406, phasors representing the A-phase, B-phase, C-phase, and zero-sequence current (310) may be generated. The zero-sequence current (310) is the sum of the three phase current and should be approximately zero in an un-faulted condition. Phasor values generated at 406 may be stored at 414 and used to identify changes in phasor values.

At 408, changes may be calculated based on prior phasor values. In some embodiments, a one-cycle difference may be used to calculate changes, or delta quantities, of phase currents.

At 410, phasors based on the delta quantities may be generated. In various embodiments, cosine and sine filters may be applied to the delta quantities generated at 408 to extract fundamental frequency components and to construct the phasors. The delta quantity phasors may be analyzed to detect SPG faults.

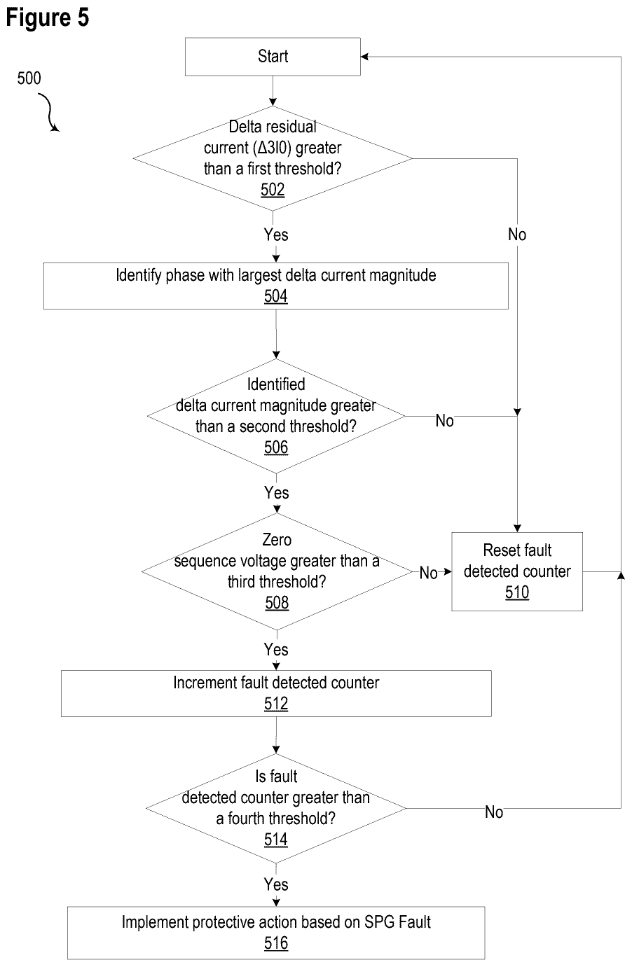

FIG. 5 illustrates a flow chart of a method 500 for identifying SPG faults consistent with embodiments of the present disclosure. In various embodiments, data flow 400, illustrated in FIG. 4, may provide information used by method 500. At 502, a delta residual current (Δ310) value may be compared to a first threshold. If the delta residual current (Δ310) is below the minimum threshold, the fault detected counter may be reset at 510 and method 500 may return to the start. Once the delta residual current exceeds the threshold, the phase (i.e., phase A, B, or C) with the largest change in current value may be identified at 504. The delta current of the identified phase change may be compared to a minimum threshold at 506. The threshold may be selected to avoid the element mis-operation under normal noisy load conditions. In some embodiments, the minimum current may be on the order of a few amps.

At 506, the identified delta current may be compared to a second threshold. If the identified delta current is not greater than the second threshold, a fault detected counter may be reset at 510 and method 500 may return to 502. Otherwise, the method advances to 508.

At 508, the zero-sequence voltage may be compared to a third threshold. If the zero sequence voltage is less than the third threshold, method 500 may return to the start after a reset of the fault detected counter at 510. In one specific embodiment, the threshold may be approximately twenty percent of the system nominal voltage.

If the zero sequence threshold is greater than the third threshold, the logic proceeds to 512 where the fault detected counter is incremented and the counter value is checked against a fourth threshold at 514. The fault detected counter threshold may be set to ensure that the conditions last for a specified amount of time to avoid being triggered based on transient conditions.

Once the faulted phase counter exceeds the threshold at 514, a protective action may be implemented at 516. A protective action may include interrupting the flow of current to the fault. Current may be interrupted by actuating a breaker through which the fault current flows.

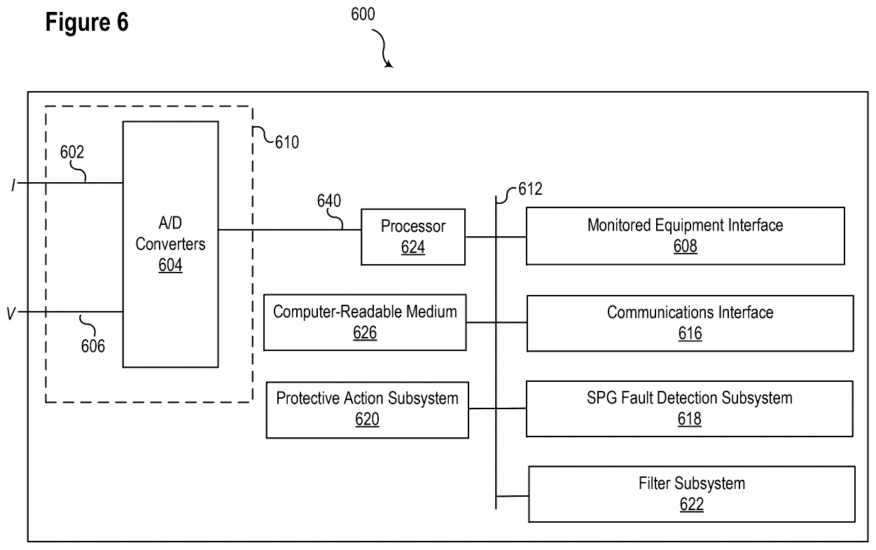

FIG. 6 illustrates a functional block diagram of a system 600 for use in an electric power system and consistent with embodiments of the present disclosure. System 600 may be implemented using hardware, software, firmware, and/or any combination thereof. In some embodiments, system 600 may be embodied as an intelligent electronic device (IED), a protective relay, a logic controller, or other types of devices. Certain components or functions described herein may be associated with other devices or performed by other devices. The specifically illustrated configuration is merely representative of one embodiment consistent with the present disclosure. In some embodiments, system 600 may be incorporated into another device, while in other embodiments, system 600 may be embodied as a distinct device.

System 600 includes a communications interface 616 to communicate with merging units, relays, IEDs, and/or other devices in an electric power system. In certain embodiments, the communications interface 616 may facilitate direct communication or communicate with systems over a communications network (not shown). A variety of types of information may be provided to system 600 via communications interface 616. In one specific embodiment, a data stream comprising a plurality of measurements associated with a remote location (i.e., the distant end of a transmission line). Communications received via communications interface 616 may include indices and timestamps generated by a remote device.

A monitored equipment interface 608 may receive status information from, and issue control instructions or protective actions to monitored equipment. In some embodiments, system 600 may perform a specific task within a power system (e.g., acting as a differential protection relay), and monitored equipment interface 608 may enable communication between system 600 and an associated piece of monitored equipment. Control instructions may include, but are not limited to actuating disconnect switches, breakers, or reclosers to selectively connect or disconnect a portion of the electric power system. Of course, commands to operate monitored equipment may also be transmitted via communications interface 616 for implementation by other devices.

Processor 624 processes communications received via communications interface 616, and/or monitored equipment interface 608. Processor 624 may operate using any number of processing rates and architectures. Processor 624 may perform various algorithms and calculations described herein. Processor 624 may be embodied as a general-purpose integrated circuit, an application-specific integrated circuit, a field-programmable gate array, and/or any other suitable programmable logic device. A data bus 612 may provide a connection between various components of system 600.

Instructions to be executed by processor 624 may be stored in computer-readable medium 626. Computer-readable medium 626 may comprise random access memory (RAM) and non-transitory memory. Computer-readable medium 626 may be the repository of software modules configured to implement the functionality described herein.

System 600 may include a sensor component 610. In the illustrated embodiment, sensor component 610 may receive current measurements 602 and/or voltage measurements 606. The sensor component 610 may comprise A/D converters 604 that sample and/or digitize filtered waveforms to form corresponding digitized current and voltage signals. Current measurements 602 and/or voltage measurements 606 may include separate signals from each phase of a three-phase electric power system. A/D converters 604 may be connected to processor 624 by way of data bus 640, through which digitized representations of electrical parameters may be transmitted. Sensor component 610 may monitor the direction of power flow.

An SPG fault detection subsystem 618 may monitor for an SPG fault based on information received by system 600. In some embodiments, SPG fault detection subsystem 618 may implement data flow 400, as illustrated in FIG. 4. Further, in some embodiments, SPG fault detection subsystem 618 may implement method 500, as illustrated in FIG. 5.

A protective action subsystem 620 may implement a protective action based on various conditions in an electric power system (e.g., detection of a SPG fault or other anomalous condition). Protective actions may include actuating a switching device to interrupt the flow of electrical current through a portion of the electric power system. Protective actions may be implemented directly by system 600 or may be communicated to other devices to be implemented.

A filter subsystem 622 may implement the filters described herein. For example, filter subsystem 622 may implement the low pass filter described in connection with data flow 400 illustrated in FIG. 4. Filter subsystem 622 may also implement the cosine and sine filters to extract fundamental frequency components associated with measurements of electrical parameters received by system 600.

While specific embodiments and applications of the disclosure have been illustrated and described, it is to be understood that the disclosure is not limited to the precise configurations and components disclosed herein. Accordingly, many changes may be made to the details of the above-described embodiments without departing from the underlying principles of this disclosure. The scope of the present invention should, therefore, be determined only by the following claims.

What is claimed:

1. A system for protection of equipment in an electric power system, comprising:
an intelligent electronic device (IED) in electrical communication with the electric power system, the IED comprising:
a fault detection subsystem to:
receive a representation of a change of an electrical current for each of a plurality of phases of the electric power system;
determine a zero-sequence current based on the representation;
determine that the zero-sequence current exceeds a first threshold;
calculate a magnitude of the change of the electrical current for each of the plurality of phases of the electric power system;
compare the magnitude of the change of the electrical current to identify a fault on a faulted phase with a magnitude exceeding a second threshold;
determine a zero-sequence voltage for the faulted phase;
compare the zero-sequence voltage for the faulted phase to a third threshold;
increment a fault detected counter while the magnitude of change in zero sequence current exceeds the first threshold, the magnitude of change in the faulted phase exceeds the second threshold, and the zero-sequence voltage exceeds the third threshold; and
identify a fault when the fault detected counter exceeds a fourth threshold.

2. The system of claim 1, wherein the fault comprises a high-impedance single-phase-ground fault.

3. The system of claim 1, wherein the representation of the change comprises a phasor for each of the plurality of phases.

4. The system of claim 1, wherein the representation of the change comprises a change from between one and five power system cycles.

5. The system of claim 1, wherein the IED further comprises a sensor component to measure the representation of the change of the electrical current from each phase of the electric power system.

6. The system of claim 1, wherein the IED further comprises a communications interface to receive the change of an electrical current.

7. The system of claim 1, wherein the IED further comprises a protective action subsystem to interrupt a flow of electrical current to the faulted phase.

8. The system of claim 1, further comprising a filter subsystem to apply a low pass filter to the representation of the change of the electrical current prior to calculation of the magnitude of the change of the electrical current.

9. The system of claim 1, wherein the electric power system comprises a three-wire distribution system.

10. The system of claim 9, wherein the electric power system further comprises one of an ungrounded or a high-impedance-grounded system.

11. A method for protecting equipment in an electric power system, comprising:
receiving a representation of a change of an electrical current for each of a plurality of phases of the electric power system;
determining a zero-sequence current based on the representation;
determining that the zero-sequence current exceeds a first threshold;
calculating a magnitude of the change of the electrical current for each of the plurality of phases of the electric power system;
comparing the magnitude of the change of the electrical current to identify a fault on a faulted phase with a magnitude exceeding a second threshold;
determining a zero-sequence voltage for the faulted phase;
comparing the zero-sequence voltage for the faulted phase to a third threshold; and
incrementing a fault detected counter while the magnitude of the change in the zero sequence current exceeds the first threshold, the magnitude of change in the faulted phase exceeds the second threshold, and the zero-sequence voltage exceeds the third threshold.

12. The method of claim 11, wherein the fault comprises a high-impedance single-phase-ground fault.

13. The method of claim 11, wherein the representation of the change comprises a phasor for each of the plurality of phases.

14. The method of claim 11, wherein the representation of the change comprises a change between one and five power system cycles.

15. The method of claim 11, wherein receiving the representation of the change of an electrical parameter from each of a plurality of phases of the electric power system comprises measuring the representation of the change of the electrical current from each phase of the electric power system using a sensor component.

16. The method of claim 11, wherein receiving the representation of the change of the electrical current comprises receiving the representation using a communications interface.

17. The method of claim 11, further comprising implementing a protective action to interrupt a flow of electrical current to the faulted phase.

18. The method of claim 11, further comprising applying a low pass filter to the representation of the change of the electrical current prior to calculating the magnitude of the change of the electrical current.

19. The method of claim 11, wherein the electric power system comprises a three-wire distribution system.

20. The method of claim 11, wherein the electric power system further comprises one of an ungrounded or a high-impedance-grounded system.
